(19) United States
(12) Patent Application Publication
(10) Pub. No.: US 2025/0176178 A1
(43) Pub. Date: May 29, 2025

(54) MEMORY DEVICE AND METHOD OF MANUFACTURING THE SAME

(71) Applicant: SK hynix Inc., Icheon-si Gyeonggi-do (KR)

(72) Inventors: Do Young KIM, Icheon-si Gyeonggi-do (KR); Eun Mee KWON, Icheon-si Gyeonggi-do (KR)

(73) Assignee: SK hynix Inc., Icheon-si Gyeonggi-do (KR)

(21) Appl. No.: 18/635,649

(22) Filed: Apr. 15, 2024

(30) Foreign Application Priority Data
Nov. 23, 2023 (KR) 10-2023-0164303

(51) Int. Cl. H10B 43/27; G11C 16/04; H10B 43/10

(52) U.S. Cl. CPC H10B 43/27; G11C 16/0483; H10B 43/10

(57) ABSTRACT

A memory device, and a method of manufacturing the same, includes a channel layer enclosing a central axis and extending in a first direction, the channel layer including a side surface depressed toward the central axis and a side surface protruding from the central axis. The memory device also includes a tunnel isolation layer enclosing an outer side surface of the channel layer and a charge trap layer enclosing an outer side surface of the tunnel isolation layer. The memory device further includes charge trap patterns enclosing a depressed portion of the charge trap layer and spaced apart from each other in the first direction. The memory device additionally includes first blocking patterns enclosing a protruding portion of the charge trap layer, second blocking patterns enclosing the charge trap patterns, and gate lines enclosing the second blocking patterns.

### CROSS-REFERENCE TO RELATED APPLICATION

The present application claims priority under 35 U.S.C. § 119(a) to Korean patent application number 10-2023-0164303, filed on Nov. 23, 2023, the entire contents of which application is incorporated herein by reference.

### BACKGROUND

### 1. Technical Field

Various embodiments of the present disclosure generally relate to a memory device and a method of manufacturing the memory device, and more particularly, to a memory device having a stacked structure and a method of manufacturing the memory device.

### 2. Related Art

A memory device may include a memory cell array in which data is stored, and a peripheral circuit which is configured to perform a program operation, a read operation, or an erase operation on the memory cell array.

The memory cell array may include a plurality of memory blocks, each of which may include a plurality of memory cells vertically stacked on a substrate.

The plurality of stacked memory cells may be formed in a cell plug.

The cell plug may include a charge trap layer extending in a vertical direction. Electrons trapped in the charge trap layer by a program operation need to remain in the memory cells even after the program operation has terminated. However, as the memory device is more highly integrated, electrons trapped in the charge trap layer of the memory cells may escape from a memory cell area and move in a downward or upward direction. Due thereto, the reliability of the memory device may be deteriorated.

### SUMMARY

A memory device in accordance with an embodiment of the present disclosure may include a channel layer enclosing a central axis and extending in a first direction, the channel layer including a side surface depressed toward the central axis and a side surface protruding from the central axis, a tunnel isolation layer enclosing an outer side surface of the channel layer, a charge trap layer enclosing an outer side surface of the tunnel isolation layer, charge trap patterns enclosing a depressed portion of the charge trap layer and spaced apart from each other in the first direction, first blocking patterns enclosing a protruding portion of the charge trap layer, second blocking patterns enclosing the charge trap patterns, and gate lines enclosing the second blocking patterns.

A method of manufacturing a memory device in accordance with an embodiment of the present disclosure may include forming an opening passing through first material layers and second material layers that are alternately stacked, modifying a side surface of the opening to an uneven structure by increasing a width between the first material layers exposed through the opening, forming a blocking layer, a charge trap layer, a tunnel isolation layer, and a channel layer along the side surface of the opening having the uneven structure, exposing a portion of the blocking layer by removing the second material layers, exposing a portion of the charge trap layer by removing the exposed blocking layer, forming charge trap patterns on the exposed charge trap layer, and forming blocking patterns on the charge trap patterns.

A memory device in accordance with an embodiment of the present disclosure may include a channel layer enclosing a central axis and extending in a first direction, the channel layer including a side surface depressed toward the central axis and a side surface protruding from the central axis; a tunnel isolation layer enclosing an outer side surface of the channel layer; first charge trap patterns contacting a surface of a depressed portion of the tunnel isolation layer and spaced apart from each other in the first direction; second charge trap patterns disposed in a depressed portion formed by the first charge trap patterns and spaced apart from each other in the first direction; blocking patterns contacting side surfaces of the second charge trap patterns; and gate lines contacting side surfaces of the blocking patterns.

A method of manufacturing a memory device in accordance with an embodiment of the present disclosure may include forming an opening passing through first material layers and second material layers that are alternately stacked, forming sacrificial layers along surfaces of the second material layers exposed through the opening, modifying a side surface of the opening to an uneven structure by increasing a width between the first material layers exposed through the opening, forming a charge trap layer, a tunnel isolation layer, and a channel layer along the side surface of the opening having the uneven structure, exposing a portion of the charge trap layer by removing the second material layers, exposing the sacrificial layers by removing the exposed portion of the charge trap layer, and forming first charge trap patterns and second charge trap patterns separated from each other, exposing the first charge trap patterns by removing the exposed sacrificial layers, forming third charge trap patterns contacting the exposed first charge trap patterns, and forming blocking patterns on the third charge trap patterns.

### BRIEF DESCRIPTION OF THE DRAWINGS

FIG. 1 is a diagram illustrating a memory device.

FIG. 2 is a diagram illustrating a memory cell array.

FIG. 3 is a diagram illustrating a memory block.

FIG. 4 is a view illustrating the structure of a memory device according to a first embodiment of the present disclosure.

FIGS. 5A to 5I are views illustrating a method of manufacturing a memory device according to a first embodiment of the present disclosure.

FIG. 6 is a view illustrating the structure of a memory device according to a second embodiment of the present disclosure.

FIGS. 7A to 7J are views illustrating a method of manufacturing a memory device according to a second embodiment of the present disclosure.

FIG. 8 is a diagram illustrating a memory card system to which a memory device according to the present disclosure is applied.

FIG. 9 is a diagram illustrating a solid-state drive (SSD) system to which a memory device according to the present disclosure is applied.

### DETAILED DESCRIPTION

Specific structural or functional descriptions, disclosed herein, are exemplified to describe embodiments according to the concept of the present disclosure. The embodiments according to the concept of the present disclosure should not be construed as being limited to the embodiments described below and may be modified in various forms and replaced with other equivalent embodiments.

Hereinafter, it will be understood that, although the terms “first” and “second” may be used herein to describe various elements, these elements should not be limited by these terms. The terms are used to distinguish one element from other elements and not to indicate a number or order of elements.

Various embodiments of the present disclosure are directed to a memory device and a method of manufacturing the memory device, which can improve the reliability of the memory device.

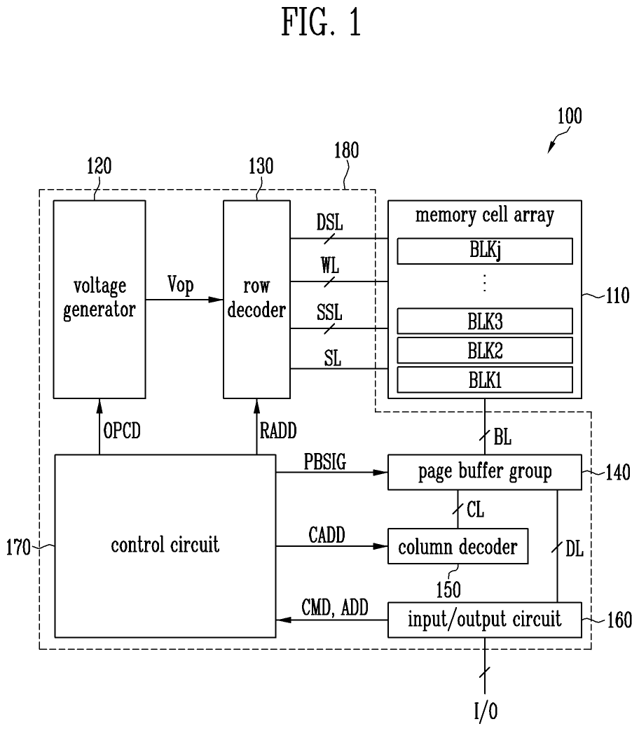

FIG. 1 is a diagram illustrating a memory device.

Referring to FIG. 1, a memory device 100 may include a memory cell array 110 and a peripheral circuit 180.

The memory cell array 110 may include first to j-th memory blocks BLK1 to BLKj. Each of the first to j-th memory blocks BLK1 to BLKj may include memory cells capable of storing data. Drain select lines DSL, word lines WL, source select lines SSL, and a source line SL may be coupled to each of the first to j-th memory blocks BLK1 to BLKj, and bit lines BL may be coupled in common to the first to j-th memory blocks BLK1 to BLKj.

Each of the first to j-th memory blocks BLK1 to BLKj may be formed to have a three-dimensional (3D) structure. Each memory block having a 3D structure may include memory cells stacked on a substrate in a vertical direction.

According to a program scheme, each memory cell may store 1 bit of data or 2 or more bits of data. For example, a scheme for storing 1 bit of data in one memory cell is referred to as a single-level cell (SLC) scheme, and a scheme for storing 2 bits of data in one memory cell is referred to as a multi-level cell (MLC) scheme. A scheme for storing 3 bits of data in one memory cell is referred to as a triple-level cell (TLC) scheme, and a scheme for storing 4 bits of data in one memory cell is referred to as a quad-level cell (QLC) scheme. In addition, 5 or more bits of data may be stored in one memory cell.

The peripheral circuit 180 may perform a program operation of storing data in the memory cell array 110, a read operation of outputting data stored in the memory cell array 110, and an erase operation of erasing data stored in the memory cell array 110. For example, the peripheral circuit 180 may include a voltage generator 120, a row decoder 130, a page buffer group 140, a column decoder 150, an input/output circuit 160, and a control circuit 170.

The voltage generator 120 may generate various operating voltages Vop that are used for a program operation, a read operation, or an erase operation in response to an operation code OPCD. For example, the voltage generator 120 may generate program voltages, turn-on voltages, turn-off voltages, negative voltages, precharge voltages, verify voltages, read voltages, pass voltages, or erase voltages in response to the operation code OPCD. The operating voltages Vop generated by the voltage generator 120 may be applied to the drain select lines DSL, the word lines WL, the source select lines SSL, and the source line SL of a memory block selected through the row decoder 130.

The program voltages may be voltages that are applied to the selected word line among the word lines WL during a program operation, and may be used to increase the threshold voltages of memory cells coupled to the selected word line. The turn-on voltages may be applied to the drain select lines DSL or the source select lines SSL, and may be used to turn on drain select transistors or source select transistors. The turn-off voltages may be applied to the drain select lines DSL or the source select lines SSL, and may be used to turn off the drain select transistors or the source select transistors. For example, the turn-off voltages may be set to 0 V. The precharge voltages may be voltages higher than 0 V, and may be applied to the bit lines during a read operation. The verify voltages may be used during a verify operation of determining whether the threshold voltages of selected memory cells have increased to a target level. The verify voltages may be set to various levels according to the target level, and may be applied to the selected word line.

The read voltages may be applied to the selected word line during a read operation performed on the selected memory cells. For example, the read voltages may be set to various levels according to the program scheme for the selected memory cells. The pass voltages may be voltages that are applied to unselected word lines among the word lines WL during a program or read operation, and may be used to turn on memory cells coupled to the unselected word lines.

The erase voltages may be used during an erase operation of erasing the memory cells included in the selected memory block, and may be applied to the source line SL.

The row decoder 130 may transmit the operating voltages Vop to the drain select lines DSL, the word lines WL, the source select lines SSL, and the source line SL, which are coupled to a memory block selected according to a row address RADD. For example, the row decoder 130 may be coupled to the voltage generator 120 through global lines GL, and may be coupled to the first to j-th memory blocks BLK1 to BLKj through the drain select lines DSL, the word lines WL, the source select lines SSL, and the source line SL.

The page buffer group 140 may include page buffers (not illustrated) coupled to the first to j-th memory blocks BLK1 to BLKj, respectively. The page buffers (not illustrated) may be coupled to the first to j-th memory blocks BLK1 to BLKj, respectively, through the bit lines BL. During a read operation, the page buffers (not illustrated) may sense the currents or voltages of the bit lines varying with the threshold voltages of the selected memory cells in response to page buffer control signals PBSIG, and may temporarily store the sensed data.

The column decoder 150 may be configured such that data is transferred between the page buffer group 140 and the input/output circuit 160 in response to a column address CADD. For example, the column decoder 150 may be coupled to the page buffer group 140 through column lines CL, and may transmit enable signals through the column lines CL. The page buffers (not illustrated) included in the page buffer group 140 may receive or output data through data lines DL in response to the enable signals.

The input/output circuit 160 may receive or output a command CMD, an address ADD, or data through input/output lines I/O. For example, the input/output circuit 160 may transmit the command CMD and the address ADD, received from an external controller through the input/output lines I/O, to the control circuit 170, and may transmit the data, received from the external controller through the input/output lines I/O, to the page buffer group 140. Alternatively, the input/output circuit 160 may output data, received from the page buffer group 140, to the external controller through the input/output lines I/O.

The control circuit 170 may output the operation code OPCD, the row address RADD, the page buffer control signals PBSIG, and the column address CADD in response to the command CMD and the address ADD. For example, when the command CMD input to the control circuit 170 is a command corresponding to a program operation, the control circuit 170 may control the devices included in the peripheral circuit 180 so that the program operation is performed on a memory block selected by the address ADD. When the command CMD input to the control circuit 170 is a command corresponding to a read operation, the control circuit 170 may control the devices included in the peripheral circuit 180 so that the read operation is performed on a memory block selected by the address and read data is output. When the command CMD input to the control circuit 170 is a command corresponding to an erase operation, the control circuit 170 may control the devices included in the peripheral circuit 180 so that the erase operation is performed on a selected memory block.

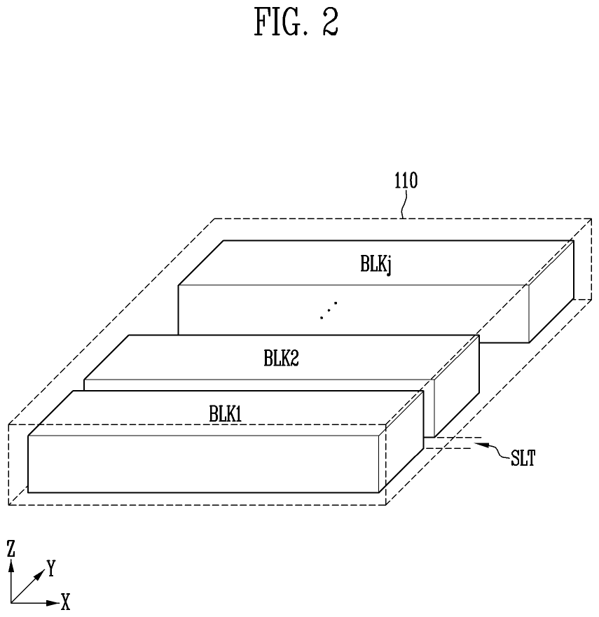

FIG. 2 is a diagram illustrating a memory cell array.

Referring to FIG. 2, the memory cell array 110 may include first to j-th memory blocks BLK1 to BLKj. Each of the first to j-th memory blocks BLK1 to BLKj may include a plurality of memory cells stacked in a three-dimensional (3D) structure. The first to j-th memory blocks BLK1 to BLKj may be arranged to be spaced apart from each other along a Y direction, and may extend along an X direction. The first to j-th memory blocks BLK1 to BLKj may be separated by slits SLT.

Although not illustrated in FIG. 2, a peripheral circuit (e.g., 180 of FIG. 1) may be disposed under or on the memory cell array 110, or may be disposed on the plane of the same substrate as the memory cell array 110.

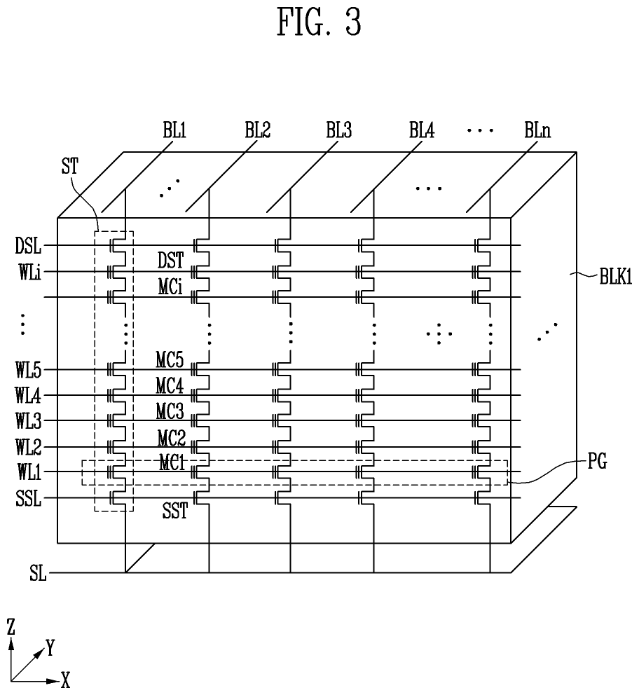

FIG. 3 is a diagram illustrating a memory block.

Referring to FIG. 3, a first memory block BLK1 among the first to j-th memory blocks BLK1 to BLKj, shown in FIG. 2, is illustrated by way of example.

The first memory block BLK1 may include a plurality of cell strings ST coupled between a source line SL and first to n-th bit lines BL1 to BLn. The cell strings ST may be coupled in common to the source line SL. Some cell strings ST among the cell strings ST may be coupled to the first to n-th bit lines BL1 to BLn, respectively, and some other cell strings ST may be coupled to the same bit line among the first to n-th bit lines BL1 to BLn. For example, the cell strings ST arranged in the X direction may be coupled to the first to n-th bit lines BL1 to BLn, respectively, and the cell strings ST arranged in the Y direction may be coupled to the same bit line.

Each of the plurality of cell strings ST may include a source select transistor SST, first to i-th memory cells MC1 to MCi, and a drain select transistor DST. A cell string ST coupled to the first bit line BL1, among the plurality of cell strings ST, will be described by way of example.

The source select transistor SST may be coupled between the source line SL and the first memory cell MC1, and the drain select transistor DST may be coupled between the i-th memory cell MCi and the first bit line BL1. The first to i-th memory cells MC1 to MCi may be coupled between the source select transistor SST and the drain select transistor DST. The number of source select transistors SST and the number of drain select transistors DST are not limited to the number illustrated in FIG. 3. In addition to the first to i-th memory cells MC1 to MCi, dummy cells (not illustrated) may be further coupled between the source select transistor SST and the drain select transistor DST. The first to i-th memory cells MC1 to MCi may store user data or normal data, and the dummy cells (not illustrated) may store dummy data.

Gates of source select transistors SST included in different cell strings ST may be coupled to the source select line SSL. Gates of the first to i-th memory cells MC1 to MCi included in different cell strings ST may be coupled to first to i-th word lines WL1 to WLi, respectively. Gates of drain select transistors DST included in different cell strings ST may be coupled to the drain select line DSL. A group of memory cells included in cell strings ST arranged in the X direction and coupled to the same word line may be a page (PG). In the memory device, a program operation or a read operation on the selected memory block may be performed on a page (PG) basis.

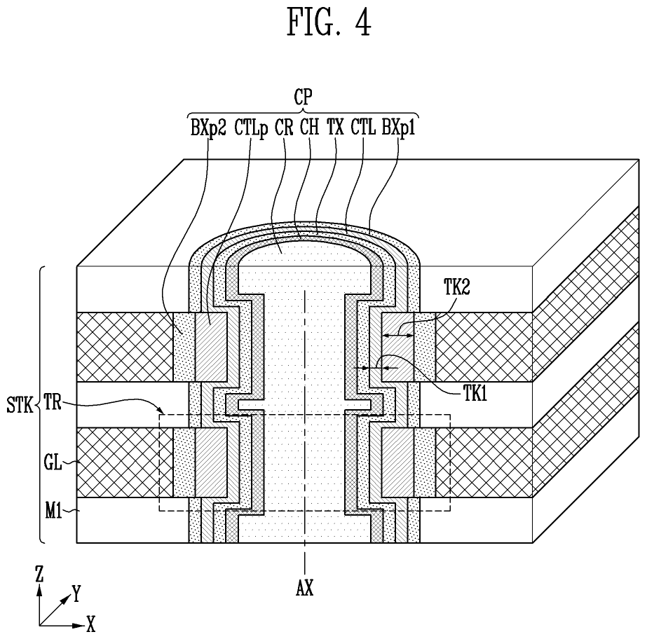

FIG. 4 is a view illustrating the structure of a memory device according to a first embodiment of the present disclosure.

Referring to FIG. 4, a portion of a memory block included in the memory device is illustrated. The memory block may include a stacked structure STK and a cell plug CP disposed in the stacked structure STK. The cell plug CP may include transistors TR constituting the cell string (e.g., ST of FIG. 3). The transistors TR may be used as select transistors or memory cells.

The stacked structure STK may include first material layers M1 and gate lines GL. Each of the first material layers M1 may be formed of an insulating material. For example, each of the first material layers M1 may be formed of an oxide layer. Each of the gate lines GL may be formed of a conductive material. For example, each of the gate lines GL may be formed of a metal material such as tungsten (W), molybdenum (Mo), cobalt (Co), or nickel (Ni), or a semiconductor material such as silicon (Si) or polysilicon (Poly-Si), but the material of the gate lines GL is not limited thereto.

The cell plug CP may penetrate the stacked structure STK. The cell plug CP may include a core pillar CR, a channel layer CH, a tunnel isolation layer TX, a charge trap layer CTL, charge trap patterns CTLp, first blocking patterns BXp1, and second blocking patterns BXp2.

The core pillar CR may be disposed in a central region of the cell plug CP, and may extend along a Z direction. For example, the core pillar CR may extend along a central axis AX vertical to an XY plane. The core pillar CR may be formed of an insulating material or a conductive material. The side surface of the core pillar CR may have an uneven structure. For example, in regions in which the first material layers M1 are located, the side surface of the core pillar CR may protrude from the central axis AX. In regions in which the gate lines GL are located, the side surface of the core pillar CR may be depressed toward the central axis AX. An interface between the depressed portions and protruding portions of the core pillar CR may form a right angle or a curved surface.

The channel layer CH may enclose the side surface of the core pillar CR. Therefore, the cross section of the channel layer CH taken along an XZ plane may have an uneven structure. The channel layer CH may be formed of polysilicon. Because the channel layer CH is formed along the side surface of the core pillar CR, the uneven structure of the channel layer CH may be an uneven structure corresponding to the core pillar CR. For example, portions of the channel layer CH depressed toward the central axis AX may contact the depressed portions of the core pillar CR, and portions of the channel layer CH protruding from the central axis AX may contact the protruding portions of the core pillar CR.

The tunnel isolation layer TX may enclose the side surface of the channel layer CH. Therefore, the cross section of the tunnel isolation layer TX taken along the XZ plane may have an uneven structure. The tunnel isolation layer TX may be formed of an insulating material. For example, the tunnel isolation layer TX may be formed of an oxide layer. Because the tunnel isolation layer TX is formed along the side surface of the channel layer CH, the uneven structure of the tunnel isolation layer TX may be an uneven structure corresponding to the channel layer CH. For example, portions of the tunnel isolation layer TX depressed toward the central axis AX may contact the depressed portions of the channel layer CH, and portions of the tunnel isolation layer TX protruding from the central axis AX may contact the protruding portions of the channel layer CH.

The charge trap layer CTL may enclose the side surface of the tunnel isolation layer TX. Therefore, the cross section of the charge trap layer CTL taken along the XZ plane may have an uneven structure. The charge trap layer CTL may be formed of a silicon nitride layer (SiN) or a silicon oxynitride layer (SiON). Because the charge trap layer CTL is formed along the side surface of the tunnel isolation layer TX, the uneven structure of the charge trap layer CTL may be an uneven structure corresponding to the tunnel isolation layer TX. For example, portions of the charge trap layer CTL depressed toward the central axis AX may contact the depressed portions of the tunnel isolation layer TX, and portions of the charge trap layer CTL protruding from the central axis AX may contact the protruding portions of the tunnel isolation layer TX.

The charge trap patterns CTLp may be disposed in the depressed portions of the charge trap layer CTL, and may be spaced apart from each other along the Z direction. Each of the charge trap patterns CTLp may be formed of a material having a higher charge trap density than that of the charge trap layer CTL. For example, each of the charge trap patterns CTLp may be formed of a silicon nitride layer. To have a higher charge trap density than that of the charge trap layer CTL, each charge trap pattern CTLp may be formed of a silicon nitride layer with a lower nitrogen content than that of the charge trap layer CTL. That is, the total charge trap density of the charge trap patterns CTLp and the charge trap layer CTL may be decreased as the concentration of nitrogen in the charge trap layer CTL is higher.

Because the charge trap patterns CTLp are located in the depressed portions of the charge trap layer CTL, side surfaces adjacent to the central axis AX, among side surfaces of the charge trap patterns CTLp, and portions of the top surfaces and portions of bottom surfaces of the charge trap patterns CTLp may contact the charge trap layer CTL. The thickness of each of the charge trap patterns CTLp may be greater than that of the charge trap layer CTL. Here, thickness may refer to the length of each of the charge trap patterns CTLp and the charge trap layer CTL in the X direction. For example, assuming that the charge trap layer CTL has a first thickness TK1 and the charge trap patterns CTLp each have a second thickness TK2, the second thickness TK2 may be greater than the first thickness TK1. Even though some of electrons trapped in the charge trap layer CTL move to the outside of the transistor TR after a program operation is terminated, electrons are also trapped in the charge trap patterns CTLp, whereby the threshold voltage of the transistor TR may be maintained. Further, because the charge trap layer CTL extending in the Z direction has the uneven structure, the length of the charge trap layer CTL in the Z direction may increase. Therefore, a phenomenon in which the electrons trapped in the charge trap layer CTL among transistors TR adjacent in the Z direction move to other transistors adjacent in the Z direction may be suppressed.

The first blocking patterns BXp1 may enclose the side surfaces of the protruding portions of the charge trap layer CTL, and may be spaced apart from each other in the Z direction. For example, the first blocking patterns BXp1 may be separated from each other in regions in which the gate lines GL are located. Each of the first blocking patterns BXp1 may be formed of an insulating material. For example, each of the first blocking patterns BXp1 may be formed of an oxide layer. Portions of the charge trap patterns CTLp may be located in regions in which the first blocking patterns BXp1 are separated.

The second blocking patterns BXp2 may enclose the outer side surfaces of the charge trap patterns CTLp, and may be spaced apart from each other in the Z direction. For example, the second blocking patterns BXp2 may be separated from each other in regions in which the first material layers M1 are located. The second blocking patterns BXp2 may be formed of the same material as the first blocking patterns BXp1. For example, each of the second blocking patterns BXp2 may be formed of an insulating material. For example, each of the second blocking patterns BXp2 may be formed of an oxide layer.

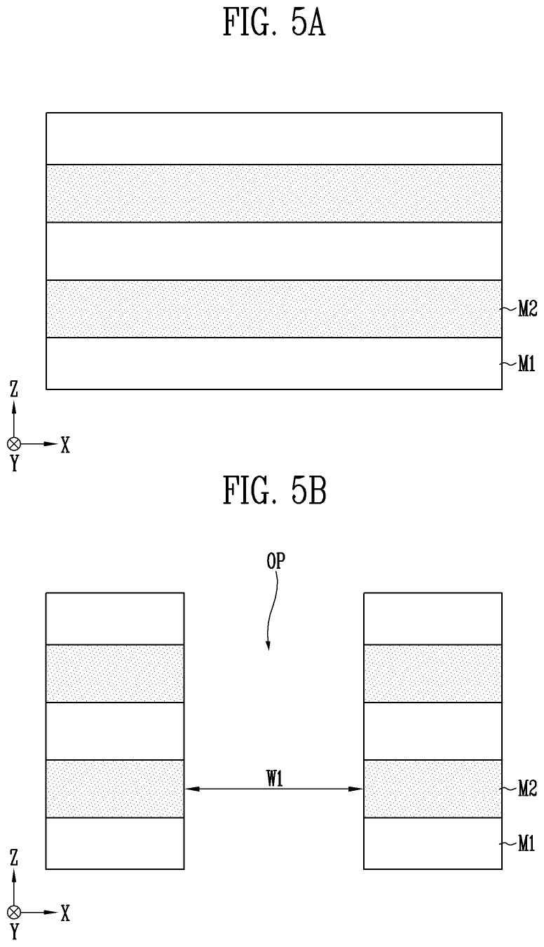

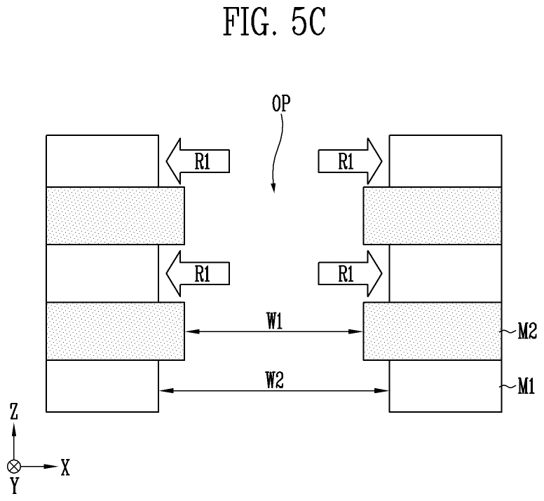

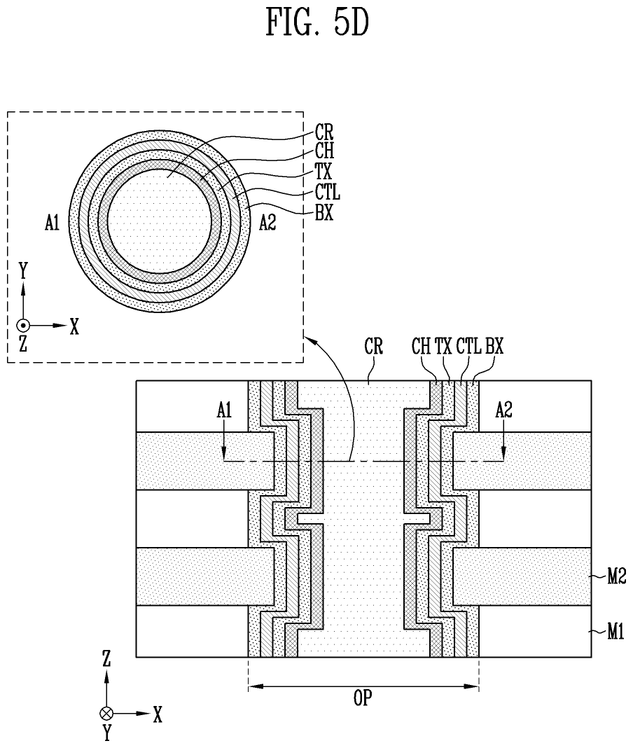

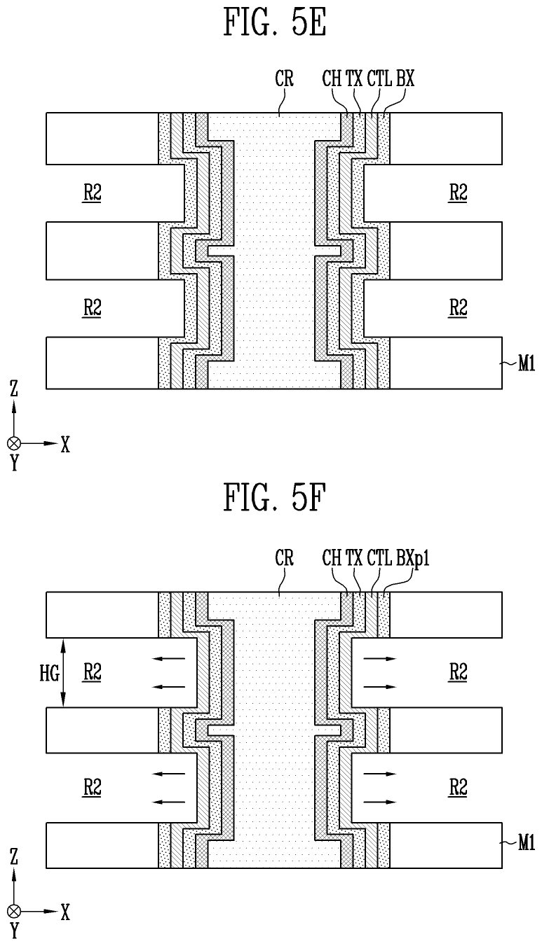

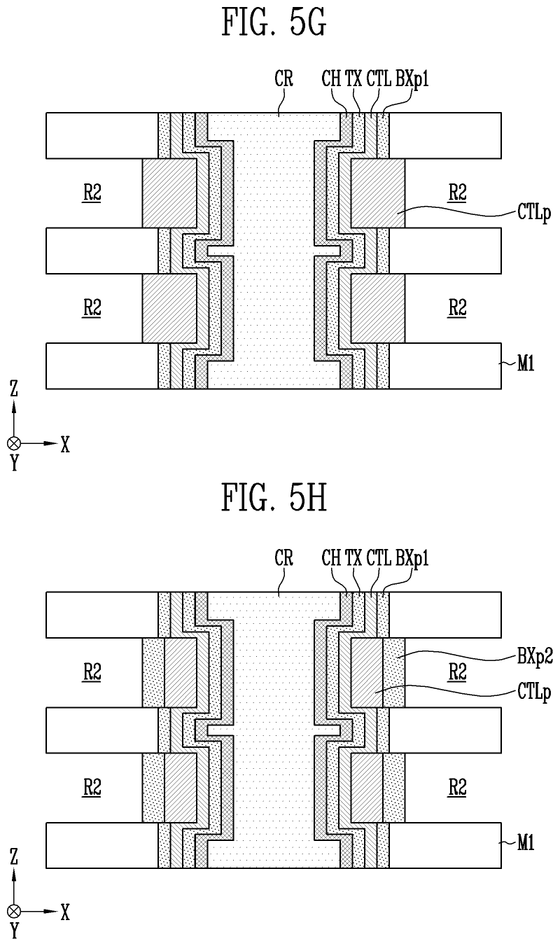

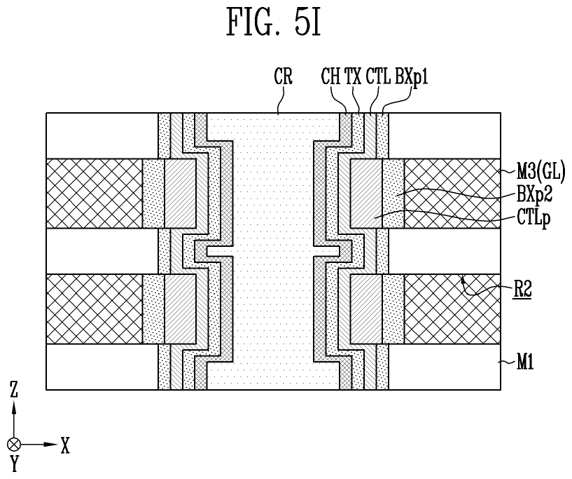

FIGS. 5A to 5I are views illustrating a method of manufacturing a memory device according to a first embodiment of the present disclosure.

Referring to FIG. 5A, first material layers M1 and second material layers M2 may be alternately stacked on a lower structure (not illustrated) along a Z direction. The lower structure (not illustrated) may be, but is not limited to, a substrate or a peripheral circuit. The first material layers M1 may be oxide layers, and the second material layers M2 may be layers formed of materials having an etch selectivity different from that of the first material layers M1. For example, the second material layers M2 may be nitride layers.

Referring to FIG. 5B, an opening OP for exposing the side surfaces of the first and second material layers M1 and M2 may be formed. The opening OP may be formed through an etching process. For example, the etching process for forming the opening OP may be performed using an anisotropic dry etching method. The opening OP may pass through the first and second material layers M1 and M2. The opening OP may have a first width W1.

Referring to FIG. 5C, first recesses R1 may be formed by removing portions of the first material layers M1 exposed through the opening OP. For example, the first recesses R1 may be formed by performing an anisotropic dry etching process or a wet etching process. Because the first recesses R1 are regions formed by removing portions of the first material layers M1, a width between the first material layers M1 exposed through the opening OP may be a second width W2 greater than a first width W1 between the second material layers M2 exposed through the opening OP. That is, due to the first recesses R1, the side surface of the opening OP may have an uneven structure.

Referring to FIG. 5D, a blocking layer BX, a charge trap layer CTL, a tunnel isolation layer TX, a channel layer CH, and a core pillar CR may be sequentially formed along the side surface of the opening OP having the uneven structure. For example, the blocking layer BX may be formed along the surface of the opening OP, and the charge trap layer CTL may be formed along the inner side surface of the blocking layer BX. The tunnel isolation layer TX may be formed along the inner side surface of the charge trap layer CTL, the channel layer CH may be formed along the inner side surface of the tunnel isolation layer TX, and the core pillar CR may fill a region enclosed by the channel layer CH. The blocking layer BX may be formed of an insulating material. For example, the blocking layer BX may be formed of an oxide layer. The charge trap layer CTL may be formed of a silicon nitride layer (SiN) or a silicon oxynitride layer (SiON). The tunnel isolation layer TX may be formed of an insulating material. For example, the tunnel isolation layer TX may be formed of an oxide layer. The channel layer CH may be formed of polysilicon. The core pillar CR may be formed of an insulating material or a conductive material.

Referring to FIG. 5E, an etching process for removing second material layers (e.g., M2 of FIG. 5D) disposed between the first material layers M1 may be performed. For example, the etching process may be performed using an anisotropic dry etching method or a wet etching method. Regions from which the second material layers M2 are removed may be second recesses R2. Therefore, through the second recesses R2, the blocking layer BX may be exposed.

Referring to FIG. 5F, an etching process for removing a portion of the blocking layer (e.g., BX of FIG. 5E) exposed through the second recesses R2 may be performed. The etching process may be performed using an anisotropic dry etching method or a wet etching method. When the blocking layer BX is etched, portions of the first material layers M1 having an etch selectivity similar to that of the blocking layer BX may also be etched. Due thereto, the height HG of the second recesses R2 between the first material layers M1 may increase compared to the height before the portion of the blocking layer BX is etched. That is, by the etching process for removing the portion of the blocking layer BX, a portion of the charge trap layer CTL may be exposed, and the volume of the second recesses R2 may increase. Portions of the blocking layer BX remaining between the second recesses R2 may become first blocking patterns BXp1. The first blocking patterns BXp1 may be disposed between the first material layers M1 and the charge trap layer CTL.

Referring to FIG. 5G, charge trap patterns CTLp may be formed in the charge trap layer CTL exposed through the second recesses R2. The charge trap patterns CTLp may be formed through a selective growth method. Therefore, the charge trap patterns CTLp may be selectively grown on the charge trap layer CTL exposed through the second recesses R2. Each of the charge trap patterns CTLp may be formed of a material having a higher charge trap density than that of the charge trap layer CTL. For example, each of the charge trap patterns CTLp may be formed of a silicon nitride layer. To have a higher charge trap density than that of the charge trap layer CTL, each of the charge trap patterns CTLp may be formed of a silicon nitride layer with a lower nitrogen content than that of the charge trap layer CTL. The charge trap patterns CTLp may be formed until the first blocking patterns BXp1 are not exposed in the second recesses R2. Therefore, after the charge trap patterns CTLp are formed, the first material layers M1 and the charge trap patterns CTLp may be exposed through the second recesses R2.

Referring to FIG. 5H, second blocking patterns BXp2 may be formed along the surfaces of the charge trap patterns CTLp exposed through the second recesses R2. The second blocking patterns BXp2 may be formed of the same material as the first blocking patterns BXp1. For example, each of the second blocking patterns BXp2 may be formed of an oxide layer. The second blocking patterns BXp2 may be formed through an oxidation method. For example, the second blocking patterns BXp2 may be formed by oxidizing portions of the charge trap patterns CTLp exposed through the second recesses R2. When the side surfaces of the charge trap patterns CTLp are oxidized, portions of the charge trap patterns CTLp become the second blocking patterns BXp2, and thus portions of the second blocking patterns BXp2 may overlap portions of the first blocking patterns BXp1. Because the second blocking patterns BXp2 may also be formed on the side surfaces of the charge trap patterns CTLp, the volume of the second recesses R2 may decrease.

Referring to FIG. 5I, third material layers M3 may be formed in the second recesses R2. Because the third material layers M3 may be used as gate lines GL, they may be formed of a conductive material. For example, each of the third material layers M3 may be formed of a metal material such as tungsten (W), molybdenum (Mo), cobalt (Co), or nickel (Ni), or a semiconductor material such as silicon (Si) or polysilicon (Poly-Si), but the material of the third material layers M3 is not limited thereto.

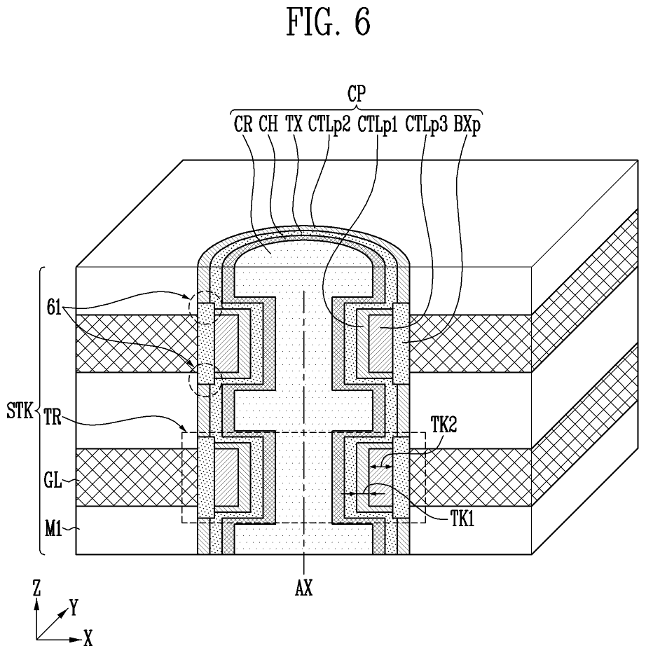

FIG. 6 is a view illustrating the structure of a memory device according to a second embodiment of the present disclosure.

Referring to FIG. 6, a portion of the memory block included in the memory device is illustrated. The memory block may include a stacked structure STK and a cell plug CP disposed in the stacked structure STK. The cell plug CP may include transistors TR constituting the cell string (e.g., ST of FIG. 3). The transistors TR may be used as select transistors or memory cells.

The stacked structure STK may include first material layers M1 and gate lines GL. Each of the first material layers M1 may be formed of an insulating material. For example, each of the first material layers M1 may be formed of an oxide layer. Each of the gate lines GL may be formed of a conductive material. For example, each of the gate lines GL may be formed of a metal material such as tungsten (W), molybdenum (Mo), cobalt (Co), or nickel (Ni), or a semiconductor material such as silicon (Si) or polysilicon (Poly-Si), but the material of the gate lines GL is not limited thereto.

The cell plug CP may penetrate the stacked structure STK. The cell plug CP may include a core pillar CR, a channel layer CH, a tunnel isolation layer TX, first charge trap patterns CTLp1, second charge trap patterns CTLp2, third charge trap patterns CTLp3, and blocking patterns BXp.

The core pillar CR may be disposed in a central region of the cell plug CP, and may extend along a Z direction. For example, the core pillar CR may extend along a central axis AX vertical to an XY plane. The core pillar CR may be formed of an insulating material or a conductive material. The side surface of the core pillar CR may have an uneven structure. For example, in regions in which the first material layers M1 are located, the side surface of the core pillar CR may protrude from the central axis AX. In regions in which the gate lines GL are disposed, the side surface of the core pillar CR may be depressed toward the central axis AX. An interface between the depressed portions and protruding portions of the core pillar CR may form a right angle or a curved surface.

The channel layer CH may enclose the side surface of the core pillar CR. Therefore, the cross section of the channel layer CH taken along an XZ plane may have an uneven structure. The channel layer CH may be formed of polysilicon. Because the channel layer CH is formed along the side surface of the core pillar CR, the uneven structure of the channel layer CH may be an uneven structure corresponding to the core pillar CR. For example, portions of the channel layer CH protruding from the central axis AX may contact the protruding portions of the core pillar CR, and portions of the channel layer CH depressed toward the central axis AX may contact the depressed portions of the core pillar CR.

The tunnel isolation layer TX may enclose the side surface of the channel layer CH. Therefore, the cross section of the tunnel isolation layer TX taken along the XZ plane may have an uneven structure. The tunnel isolation layer TX may be formed of an insulating material. For example, the tunnel isolation layer TX may be formed of an oxide layer. Because the tunnel isolation layer TX is formed along the side surface of the channel layer CH, the uneven structure of the tunnel isolation layer TX may be an uneven structure corresponding to the channel layer CH. For example, portions of the tunnel isolation layer TX protruding from the central axis AX may contact the protruding portions of the channel layer CH, and portions of the tunnel isolation layer TX depressed toward the central axis AX may contact the depressed portions of the channel layer CH.

The first charge trap patterns CTLp1 may be formed along the depressed surface of the tunnel isolation layer TX, and may be spaced apart from each other along the Z direction. Each of the first charge trap patterns CTLp1 may be formed of a silicon nitride layer (SiN) or a silicon oxynitride layer (SiON). Each of the first charge trap patterns CTLp1 may be formed along the top surface, the bottom surface, and the side surface of the corresponding depressed portion of the tunnel isolation layer TX.

Each of the second charge trap patterns CTLp2 may enclose the surface of the corresponding protruding portion of the tunnel isolation layer TX. For example, the second charge trap patterns CTLp2 may be disposed between the first material layers M1 and the tunnel isolation layer TX. The second charge trap patterns CTLp2 may be spaced apart from each other along the Z direction. The second charge trap patterns CTLp2 may be separated from the first charge trap patterns CTLp1. The second charge trap patterns CTLp2 may be formed of the same material as the first charge trap patterns CTLp1. For example, each of the second charge trap patterns CTLp2 may be formed of a silicon nitride layer (SiN) or a silicon oxynitride layer (SiON).

The third charge trap patterns CTLp3 may be disposed in regions enclosed by the first charge trap patterns CTLp1, and may be spaced apart from each other along the Z direction.

The third charge trap patterns CTLp3 may be formed of a material having a higher charge trap density than that of the first charge trap patterns CTLp1. For example, each of the third charge trap patterns CTLp3 may be formed of a silicon nitride layer. To have a higher charge trap density than that of the first charge trap patterns CTLp1, each of the third charge trap patterns CTLp3 may be formed of a silicon nitride layer having a lower nitrogen content than that of the first charge trap patterns CTLp1.

Because the third charge trap patterns CTLp3 are located in the depressed portions of the first charge trap patterns CTLp1, a side surface adjacent to the central axis AX, among the side surfaces of the third charge trap patterns CTLp3, and the top surfaces and bottom surfaces of the third charge trap patterns CTLp3 may contact the first charge trap patterns CTLp1. The thickness of each of the third charge trap patterns CTLp3 may be greater than that of each of the first charge trap patterns CTLp1. Here, thickness denotes the length of each of the third charge trap patterns CTLp3 and the first charge trap patterns CTLp1 in the X direction. For example, assuming that each first charge trap patterns CTLp1 has a first thickness TK1 and each third charge trap patterns CTLp3 has a second thickness TK2, the second thickness TK2 may be greater than the first thickness TK1. Therefore, during a program operation, electrons may be trapped in the first charge trap patterns CTLp1 and the third charge trap patterns CTLp3. The first charge trap patterns CTLp1 and the third charge trap patterns CTLp3 may be separated from each other by the blocking patterns BXp (61). Because the first charge trap patterns CTLp1 and the third charge trap patterns CTLp3 disposed in different layers are spaced apart from each other along the Z direction, a phenomenon in which electrons trapped in the first charge trap patterns CTLp1 move in a downward or upward direction during a program operation may be mitigated or prevented. Therefore, after the program operation is terminated, the threshold voltage of the transistor TR may be maintained.

The blocking patterns BXp may contact the side surfaces of the first charge trap patterns CTLp1 and the third charge trap patterns CTLp3, and may be spaced apart from each other along the Z direction. For example, the blocking patterns BXp may enclose the side surfaces of the first charge trap patterns CTLp1 and the third charge trap patterns CTLp3. The blocking patterns BXp may be disposed between each of the first charge trap patterns CTLp1 and the third charge trap patterns CTLp3 and the gate lines GL. The blocking patterns BXp may be disposed between the second charge trap patterns CTLp2 disposed in different layers. The blocking patterns BXp may separate the first charge trap patterns CTLp1 and the second charge trap patterns CTLp2 from each other (61). Each of the blocking patterns BXp may be formed of an insulating material. For example, each of the blocking patterns BXp may be formed of an oxide layer.

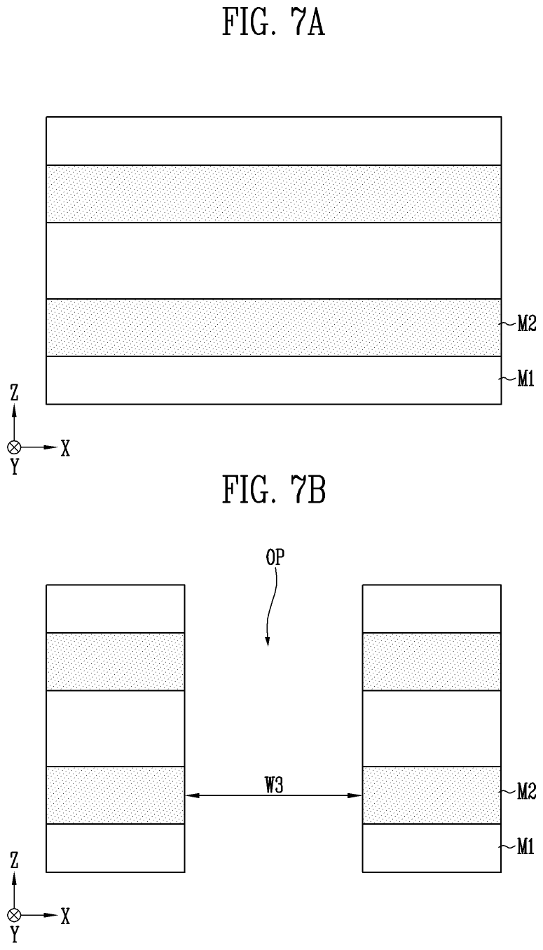

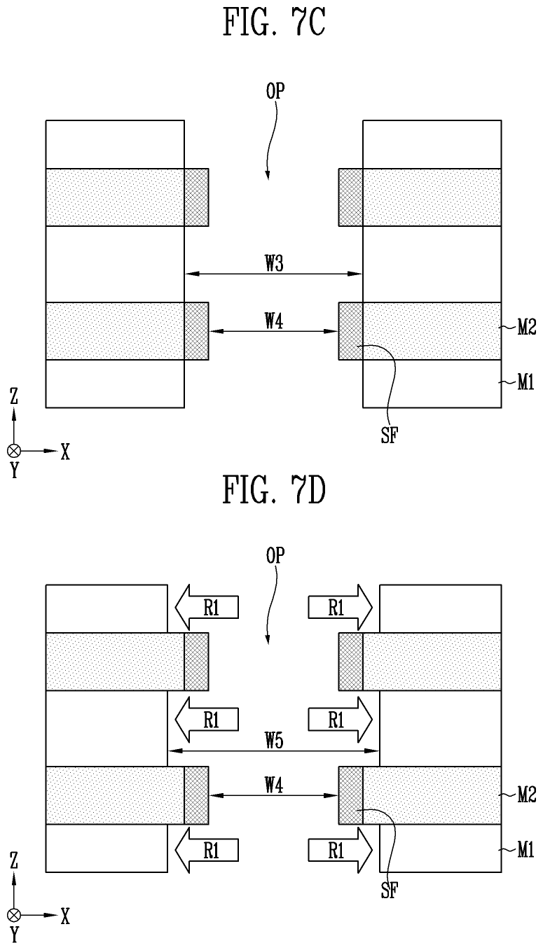

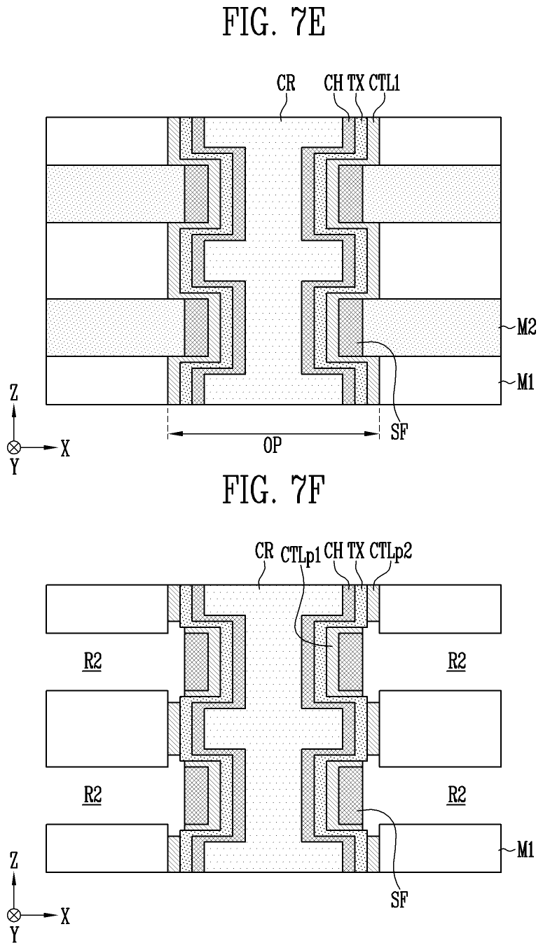

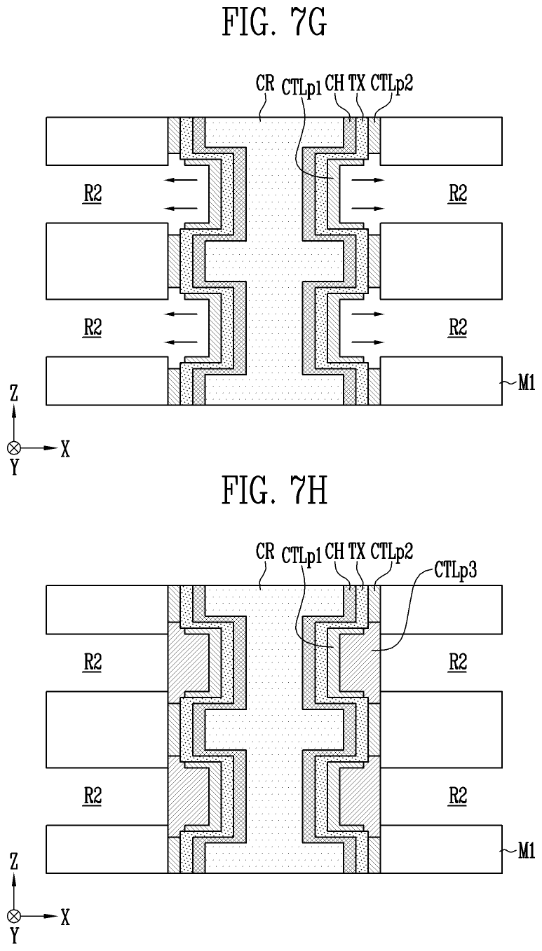

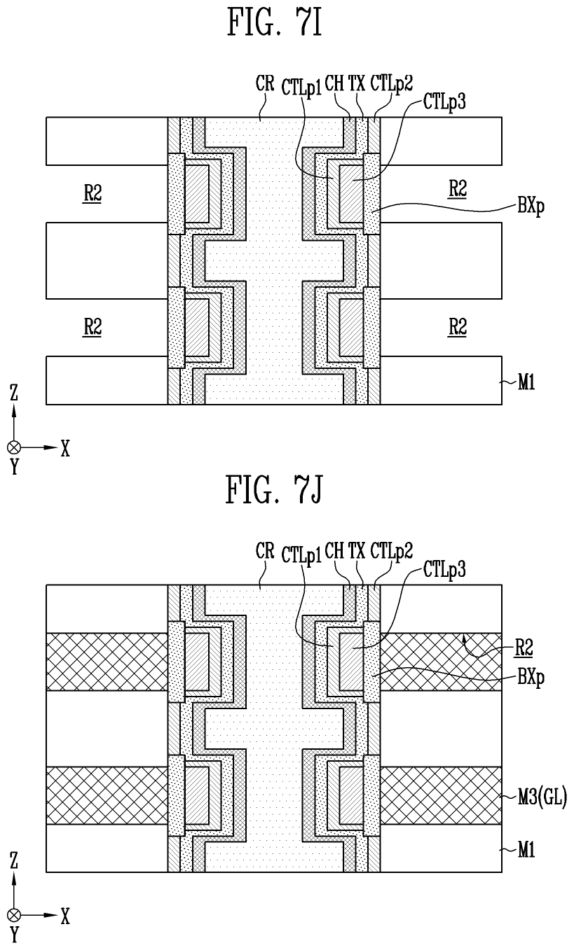

FIGS. 7A to 7J are views illustrating a method of manufacturing a memory device according to a second embodiment of the present disclosure.

Referring to FIG. 7A, first material layers M1 and second material layers M2 may be alternately stacked on a lower structure (not illustrated) along a Z direction. The lower structure (not illustrated) may be, but is not limited to, a substrate or a peripheral circuit. The first material layers M1 may be oxide layers, and the second material layers M2 may be layers made of materials having an etch selectivity different from that of the first material layers M1. For example, the second material layers M2 may be nitride layers.

Referring to FIG. 7B, an opening OP for exposing the side surfaces of the first and second material layers M1 and M2 may be formed. The opening OP may be formed through an etching process. For example, the etching process for forming the opening OP may be performed using an anisotropic dry etching method. The opening OP may pass through the first and second material layers M1 and M2. The opening OP may have a third width W3.

Referring to FIG. 7C, sacrificial layers SF may be selectively formed on the side surfaces of the second material layers M2 exposed through the opening OP. For example, the sacrificial layers SF may be formed of SiOC. Each of the sacrificial layers SF may have a thickness at which the sacrificial layers SF are prevented from contacting each other. Therefore, a fourth width W4 between the sacrificial layers SF facing each other in the opening OP may be less than the third width W3 between the first material layers M1.

Referring to FIG. 7D, first recesses R1 may be formed by removing portions of the first material layers M1 exposed through the opening OP. For example, the first recesses R1 may be formed by performing an anisotropic dry etching process or a wet etching process. Because the first recesses R1 are regions formed by removing portions of the first material layers M1, a width between the first material layers M1 exposed through the opening OP may be a fifth width W5 greater than the third width W3. That is, the side surfaces of the first material layers M1, portions of the second material layers M2, and the sacrificial layers SF may be exposed through the first recesses R1. Due to the first recesses R1, the side surface of the opening OP may have an uneven structure.

Referring to FIG. 7E, a first charge trap layer CTL1, a tunnel isolation layer TX, a channel layer CH, and a core pillar CR may be sequentially formed along the side surface of the opening OP having the uneven structure. For example, the first charge trap layer CTL1 may be formed along the surface of the opening OP. The tunnel isolation layer TX may be formed along the inner side surface of the first charge trap layer CTL1, the channel layer CH may be formed along the inner side surface of the tunnel isolation layer TX, and the core pillar CR may fill a region enclosed by the channel layer CH. The first charge trap layer CTL1 may be formed of a silicon nitride layer (SiN) or a silicon oxynitride layer (SiON). The tunnel isolation layer TX may be formed of an insulating material. For example, the tunnel isolation layer TX may be formed of an oxide layer. The channel layer CH may be formed of polysilicon. The core pillar CR may be formed of an insulating material or a conductive material.

Referring to FIG. 7F, an etching process for removing the second material layers (e.g., M2 of FIG. 7E) disposed between the first material layers M1 and portions of the first charge trap layer (e.g., CTL1 of FIG. 7E) may be performed. After a first etching process for removing the second material layers M2 disposed between the first material layers M1 is performed, a second etching process for removing the portions of the first charge trap layer (e.g., CTL1 of FIG. 7E) exposed as the second material layers M2 are removed may be performed. Each of the first and second etching processes may be performed using an anisotropic dry etching method or a wet etching method. Regions from which the second material layers M2 and the portions of the first charge trap layer CTL1 are removed may become second recesses R2. When the portions of the first charge trap layer CTL1 are removed, the first charge trap layer CTL1 may be separated into first charge trap patterns CTLp1 contacting the sacrificial layers SF and second charge trap patterns CTLp2 contacting the first material layers M1.

Referring to FIG. 7G, an etching process for removing the sacrificial layers (e.g., SF of FIG. 7F) exposed through the second recesses R2 may be performed. The etching process may be performed using an anisotropic dry etching method or a wet etching method.

Referring to FIG. 7H, third charge trap patterns CTLp3 may be formed along the first charge trap patterns CTLp1 and the second charge trap patterns CTLp2 which are exposed through the second recesses R2. The third charge trap patterns CTLp3 may be formed through a selective growth method. The third charge trap patterns CTLp3 may be formed of a material having a higher charge trap density than that of the first charge trap patterns CTLp1. For example, each of the third charge trap patterns CTLp3 may be formed of a silicon nitride layer. To have a higher charge trap density than that of the first charge trap patterns CTLp1, each of the third charge trap patterns CTLp3 may be formed of a silicon nitride layer having a lower nitrogen content than that of the first charge trap patterns CTLp1. After the third charge trap patterns CTLp3 are formed, the first material layers M1 and the third charge trap patterns CTLp3 may be exposed through the second recesses R2.

Referring to FIG. 7I, blocking patterns BXp may be formed along the surfaces of the third charge trap patterns CTLp3 exposed through the second recesses R2. Each of the blocking patterns BXp may be formed of an insulating layer. The blocking patterns BXp may be formed through an oxidation method. For example, the blocking patterns BXp may be formed by oxidizing portions of the third charge trap patterns CTLp3 exposed through the second recesses R2. When the side surfaces of the third charge trap patterns CTLp3 are oxidized, portions of the third charge trap patterns CTLp3 become the blocking patterns BXp, and thus portions of the blocking patterns BXp may overlap portions of the tunnel isolation layer TX. Therefore, the blocking patterns BXp may be disposed between the first charge trap patterns CTLp1 and the second charge trap patterns CTLp2.

Referring to FIG. 7J, third material layers M3 may be formed in the second recesses R2. Because the third material layers M3 may be used as gate lines GL, indicated in FIG. 7J as “M3(GL),” they may be formed of a conductive material. For example, each of the third material layers M3 may be formed of a metal material such as tungsten (W), molybdenum (Mo), cobalt (Co), or nickel (Ni), or a semiconductor material such as silicon (Si) or polysilicon (Poly-Si), but the material of the third material layers M3 is not limited thereto.

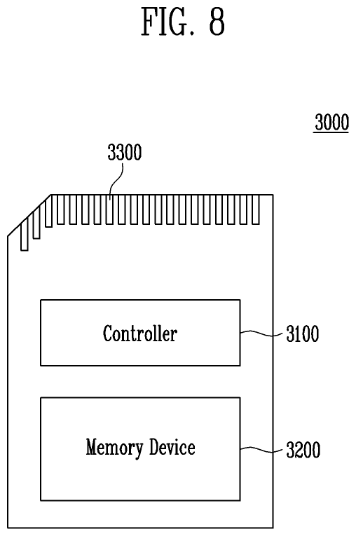

FIG. 8 is a diagram illustrating a memory card system to which a memory device according to an embodiment of the present disclosure is applied.

Referring to FIG. 8, a memory card system 3000 includes a controller 3100, a memory device 3200, and a connector 3300.

The controller 3100 is coupled to the memory device 3200. The controller 3100 may access the memory device 3200. For example, the controller 3100 may control a program, a read, or an erase operation of the memory device 3200 or control background operations of the memory device 3200. The controller 3100 may provide an interface between the memory device 3200 and a host. The controller 3100 may run firmware for controlling the memory device 3200. In an embodiment, the controller 3100 may include components, such as RAM, a processor, a host interface, a memory interface, and an error correction circuit.

The controller 3100 may communicate with an external device through the connector 3300. The controller 3100 may communicate with an external device (e.g., a host) based on a specific communication standard. In an embodiment, the controller 3100 may communicate with the external device through at least one of various communication standards such as universal serial bus (USB), multimedia card (MMC), embedded MMC (eMMC), peripheral component interconnection (PCI), PCI-express (PCI-E), an advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe). In an embodiment, the connector 3300 may be defined by at least one of the above-described various communication standards.

The memory device 3200 may include a plurality of memory cells, and for an embodiment, and may be configured in the same manner as the memory device 100 illustrated in FIG. 1.

The controller 3100 and the memory device 3200 may be integrated into a single semiconductor device to form a memory card. For example, the controller 3100 and the memory device 3200 may be integrated into a single semiconductor device and may then form a memory card such as a PC card (personal computer memory card international association: PCMCIA), a compact flash card (CF), a smart media card (SM or SMC), a memory stick, a multimedia card (MMC, RS-MMC, MMCmicro or eMMC), a SD card (SD, miniSD, microSD, or SDHC), universal flash storage (UFS), or the like.

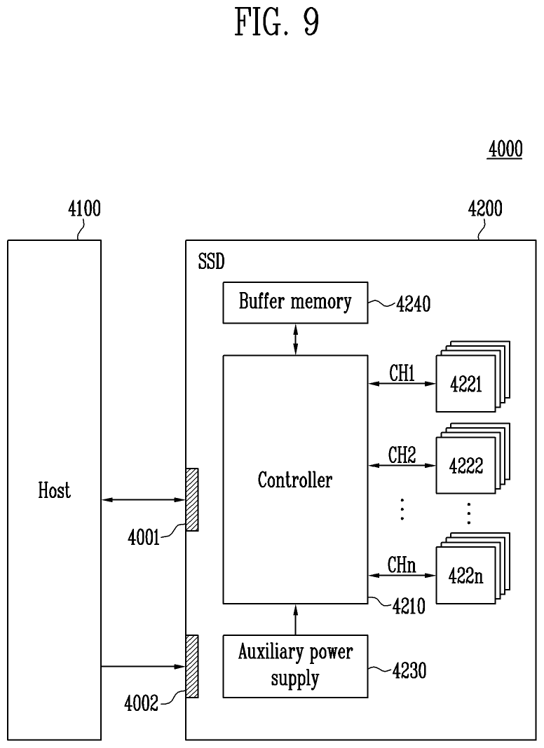

FIG. 9 is a diagram illustrating a solid-state drive (SSD) system to which a memory device according to an embodiment of the present disclosure is applied.

Referring to FIG. 9, an SSD system 4000 includes a host 4100 and an SSD 4200. The SSD 4200 may exchange a signal with the host 4100 through a signal connector 4001 and may receive power through a power connector 4002. The SSD 4200 may include a controller 4210, a plurality of memory devices 4221 to 422n, an auxiliary power supply 4230, and buffer memory 4240.

The controller 4210 may control the plurality of memory devices 4221 to 422n in response to a signal received from the host 4100. In an embodiment, the signal may include signals based on the interfaces of the host 4100 and the SSD 4200. For example, the signal may be a signal defined by at least one of interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe).

Each of the plurality of memory devices 4221 to 422n may include a plurality of memory cells which store data. Each of the plurality of memory devices 4221 to 422n may be configured in the same manner as the memory device 100 illustrated in FIG. 1. The plurality of memory devices 4221 to 422n may communicate with the controller 4210 through channels CH1 to CHn.

The auxiliary power supply 4230 may be coupled to the host 4100 through the power connector 4002. The auxiliary power supply 4230 may be supplied with a supply voltage from the host 4100 and may be charged. The auxiliary power supply 4230 may provide the supply voltage of the SSD 4200 when the supply of power from the host 4100 is not smoothly performed. In an embodiment, the auxiliary power supply 4230 may be located inside the SSD 4200 or located outside the SSD 4200. For example, the auxiliary power supply 4230 may be located on a main board and may also provide auxiliary power to the SSD 4200.

The buffer memory 4240 functions as buffer memory of the SSD 4200. For example, the buffer memory 4240 may temporarily store data received from the host 4100 or data received from the plurality of memory devices 4221 to 422n or may temporarily store metadata (e.g., mapping tables) of the memory devices 4221 to 422n. The buffer memory 4240 may include volatile memory, such as a DRAM, SDRAM, DDR SDRAM, and LPDDR SDRAM, or nonvolatile memory, such as an FRAM, ReRAM, STT-MRAM, and PRAM.

The present disclosure may, for some embodiments, improve the reliability of a memory device.

What is claimed is:

1. A memory device, comprising:
a channel layer enclosing a central axis and extending in a first direction, the channel layer including a side surface depressed toward the central axis and a side surface protruding from the central axis;
a tunnel isolation layer enclosing an outer side surface of the channel layer;
a charge trap layer enclosing an outer side surface of the tunnel isolation layer;
charge trap patterns enclosing a depressed portion of the charge trap layer and spaced apart from each other in the first direction;
first blocking patterns enclosing a protruding portion of the charge trap layer;
second blocking patterns enclosing the charge trap patterns; and
gate lines enclosing the second blocking patterns.

2. The memory device according to claim 1, wherein:
an inner side surface of each of the charge trap patterns contacts the charge trap layer,
an outer side surface of each of the charge trap patterns contacts the second blocking patterns, and
a top surface and a bottom surface of each of the charge trap patterns contact the charge trap layer and the first blocking patterns.

3. The memory device according to claim 1, wherein the charge trap layer is formed of a material having a charge trap density lower than that of the charge trap patterns.

4. The memory device according to claim 1, wherein the charge trap layer and the charge trap patterns comprise silicon nitride layers.

5. The memory device according to claim 4, wherein each of the charge trap patterns has a lower nitrogen content than that of the charge trap layer.

6. The memory device according to claim 1, wherein the charge trap layer is a silicon oxynitride layer.

7. The memory device according to claim 1, wherein the charge trap layer has a thickness less than that of each of the charge trap patterns.

8. The memory device according to claim 1, wherein outer side surfaces of the charge trap patterns protrude from the depressed portion of the charge trap layer.

9. The memory device according to claim 1, wherein outer side surfaces of the second blocking patterns protrude from the first blocking patterns.

10. The memory device according to claim 1, further comprising:
first material layers disposed between the gate lines and contacting side surfaces of the first blocking patterns.

11. The memory device according to claim 1, wherein the tunnel isolation layer, the first blocking patterns, and the second blocking patterns comprise oxide layers.

12. The memory device according to claim 1, wherein the channel layer is formed of polysilicon.

13. A method of manufacturing a memory device, comprising:
forming an opening passing through first material layers and second material layers that are alternately stacked;
modifying a side surface of the opening to an uneven structure by increasing a width between the first material layers exposed through the opening;
forming a blocking layer, a charge trap layer, a tunnel isolation layer, and a channel layer along the side surface of the opening having the uneven structure;
exposing a portion of the blocking layer by removing the second material layers;
exposing a portion of the charge trap layer by removing the exposed blocking layer;
forming charge trap patterns on the exposed charge trap layer; and
forming blocking patterns on the charge trap patterns.

14. The method according to claim 13, wherein the first material layers are formed of oxide layers, and the second material layers are formed of nitride layers.

15. The method according to claim 13, wherein modifying the side surface of the opening to the uneven structure comprises:
performing an anisotropic dry etching process or a wet etching process.

16. The method according to claim 13, wherein the blocking layer, the blocking patterns, and the tunnel isolation layer are formed of oxide layers.

17. The method according to claim 13, wherein the charge trap layer and the charge trap patterns are formed of silicon nitride layers.

18. The method according to claim 17, wherein each of the charge trap patterns has a lower nitrogen content than that of the charge trap layer.

19. The method according to claim 17, wherein the charge trap layer is formed of a silicon oxynitride layer.

20. The method according to claim 13, wherein the charge trap patterns are formed along a surface of the charge trap layer.
